(19) United States
(12) Patent Application Publication
(10) Pub. No.: US 2026/0280497 A1
(43) Pub. Date: Sep. 17, 2026

(54) TWO-STAGE POWER AMPLIFIER

(71) Applicant: Renesas Electronics America Inc., Milpitas, CA (US)

(72) Inventors: Rohit Reddy KARNATY, Milpitas, CA (US); Shishir Ramasare SHUKLA, San Diego, CA (US); Ramzi DARRAJI, Ottawa (CA); Sagar Kumar DHAR; Ramanujam SRINIDHI EMBAR, San Diego, CA (US)

(73) Assignee: Renesas Electronics America Inc., Milpitas, CA (US)

(21) Appl. No.: 19/076,111

(22) Filed: Mar. 11, 2025

(51) Int. Cl. H03F 1/56; H03F 3/21; H03F 3/213

(52) U.S. Cl. CPC H03F 1/565; H03F 3/211; H03F 3/213; H03F 2200/423; H03F 2200/451

(57) ABSTRACT

An integrated circuit includes a driver stage and a final stage. The driver stage is configured to receive an input signal and provide an amplified signal. The final stage includes a splitter, a main amplifier, a peak amplifier, a main output matching network, and a peak output matching network. The splitter is configured to receive the amplified signal and split the amplified signal into a main input signal and a peak input signal. The main amplifier is configured to receive the main input signal and provide an amplified main signal. The peak amplifier is configured to receive the peak input signal to provide an amplified peak signal. The main output matching network is coupled to the main amplifier and includes a first series inductor. The peak output matching network is coupled to the peak amplifier and includes a second series inductor.

### BACKGROUND

The present disclosure relates in general to power amplification systems and devices. Particularly, a two-stage power amplifier is described.

Wireless communication systems may employ power amplifiers for increasing the power of radio frequency (RF) signals. In a wireless communication system, a power amplifier in a final amplification stage of a transmission channel may facilitate amplification of a signal to an antenna for radiation over the air. High gain, high linearity, stability, and a high level of power-added efficiency are characteristics of a desirable amplifier in such a wireless communication system. In general, a power amplifier may operate at maximum power efficiency when the power amplifier transmits close to saturated power. However, power efficiency may degrade as output power decreases. Therefore, a high efficiency power amplifier architecture may be desirable for current and next-generation wireless systems.

### SUMMARY

In one aspect, an integrated circuit is generally described. The integrated circuit can include a driver stage and a final stage. The driver stage is configured to receive an input signal and provide an amplified signal based on the input signal. The final stage is coupled to the driver stage and configured to generate an output signal. The final stage can include a splitter, a main amplifier, a peak amplifier, a main output matching network, and a peak output matching network. The splitter is configured to receive the amplified signal from the driver stage and split the amplified signal into a main input signal and a peak input signal. The main amplifier is coupled to the splitter and configured to receive the main input signal and provide an amplified main signal. The peak amplifier is coupled to the splitter and configured to receive the peak input signal to provide an amplified peak signal. The main output matching network is coupled to the main amplifier. The main output matching network can include a first series inductor. The peak output matching network is coupled to the peak amplifier. The peak output matching network can include a second series inductor.

In one aspect, a system is generally described. The system can include a plurality of antennas and a transmission path coupled to the plurality of antennas. The transmission path can include an amplifier module. The amplifier module can include a driver stage and a final stage. The driver stage is configured to receive an input signal and provide an amplified signal based on the input signal. The final stage is coupled to the driver stage and configured to generate an output signal. The final stage can include a splitter, a main amplifier, a peak amplifier, a main output matching network, and a peak output matching network. The splitter is configured to receive the amplified signal from the driver stage and split the amplified signal into a main input signal and a peak input signal. The main amplifier is coupled to the splitter and configured to receive the main input signal and provide an amplified main signal. The peak amplifier is coupled to the splitter and configured to receive the peak input signal to provide an amplified peak signal. The main output matching network is coupled to the main amplifier. The main output matching network can include a first series inductor. The peak output matching network is coupled to the peak amplifier. The peak output matching network can include a second series inductor.

In one aspect, a system is generally described. The system can include a plurality of antennas and a receiver path coupled to the plurality of antennas. The receiver path can include an amplifier module. The amplifier module can include a driver stage and a final stage. The driver stage is configured to receive an input signal and provide an amplified signal based on the input signal. The final stage is coupled to the driver stage and configured to generate an output signal. The final stage can include a splitter, a main amplifier, a peak amplifier, a main output matching network, and a peak output matching network. The splitter is configured to receive the amplified signal from the driver stage and split the amplified signal into a main input signal and a peak input signal. The main amplifier is coupled to the splitter and configured to receive the main input signal and provide an amplified main signal. The peak amplifier is coupled to the splitter and configured to receive the peak input signal to provide an amplified peak signal. The main output matching network is coupled to the main amplifier. The main output matching network can include a first series inductor. The peak output matching network is coupled to the peak amplifier. The peak output matching network can include a second series inductor.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram showing an example system that can implement a two-stage power amplifier in one embodiment.

FIG. 2 is a diagram showing an example of a two-stage power amplifier in one embodiment.

FIG. 3A is a diagram showing an example of the final stage with matching networks in one embodiment.

FIG. 3B is a diagram showing another example of the final stage with matching networks in one embodiment.

FIG. 3C is a diagram showing an example of the final stage with matching networks and drain bias inductors in one embodiment.

FIG. 3D is a diagram showing another example of the final stage with matching networks and a drain bias inductor of one embodiment.

FIG. 4A is a diagram showing an example circuit including a matching network in one embodiment.

FIG. 4B is a diagram showing an example circuit including a matching network in one embodiment.

FIG. 5 is a diagram showing a Smith chart representing the impedance matching trajectory in the RF circuit design of one embodiment, in the context of improving bandwidth for power amplifies.

FIG. 6A shows a diagram illustrating a comparison between the bandwidth performance of a two-stage power amplifier with a matching network with series inductors and the bandwidth performance of a two-stage power amplifier with a matching network without series inductors.

FIG. 6B shows a diagram illustrating another comparison between the bandwidth performance of a two-stage power amplifier with a matching network with series inductors and the bandwidth performance of a two-stage power amplifier with a matching network without series inductors.

FIG. 7A shows a diagram illustrating a comparison between the large signal performance of a two-stage power amplifier with a matching network with series inductors and the large signal performance of a two-stage power amplifier with a matching network without series inductors.

FIG. 7B shows a diagram illustrating another comparison between the large signal performance of a two-stage power amplifier with a matching network with series inductors and the large signal performance of a two-stage power amplifier with a matching network without series inductors.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

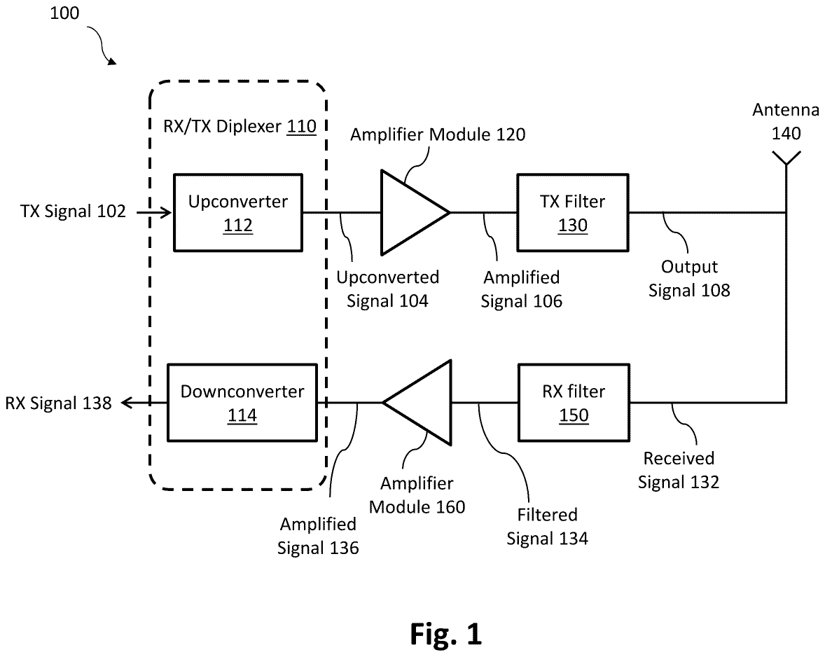

FIG. 1 is a diagram showing an example system 100 that can implement a two-stage power amplifier in one embodiment. System 100 in FIG. 1 can be part of a radio frequency (RF) transceiver, or other types of RF communication devices such as beamforming integrated circuits (ICs), that includes a plurality of communication channels connected to a phased array including a plurality of antenna elements. Referring to FIG. 1, system 100 can include a RX (Receiver)/TX (Transmitter) diplexer 110, an amplifier module 120, a transmission (TX) filter 130, an antenna 140, a RX (Receiver) filter 150 and an amplifier module 166 among the phased array. RX/TX diplexer 110 can include an upconverter 112 and a downconverter 114.

System 100 can include a transmitter path and a receiver path. The transmitter path can be implemented for generating signals to be transmitted from antenna 140 and the receiver path can be implemented for processing signals received by antenna 140. The transmitter path can include at least the upconverter 112, the amplifier module 120 and the TX filter 130. A transmission (TX) signal 102 encoding data representing information and/or messages can be provided to the transmitter path via the upconverter 112. The transmitter path can upconvert, amplify and filter the TX signal 102 to generate an output signal 108 encoding the same data as TX signal 102. Output signal 108 can be RF signals. Output signal 108 can be provided to the antenna 140 and antenna 140 can emit radio waves representing output signal 108 to wirelessly transmit output signal 108 to a destination device through a medium, such as air.

Upconverter 112 can receive TX signal 102. Upconverter 112 can be configured to convert TX signal 102 into an upconverted signal 104 that has a higher frequency than TX signal 102. Amplifier module 120 can receive upconverted signal 104 from upconverter 112. Amplifier module 120 can be a power amplifier configured to amplify upconverted signal 104 into an amplified signal 106. Amplifier module 120 can boost the signal strength or gain, or increase the power level, of upconverted signal 104 to a level suitable for transmission over long distances or through various mediums. Amplifier module 120 can be implemented as a two-stage power amplifier with peak output match integrated in the final stage to improve efficiency at high frequency applications. The increased signal strength can also extend the coverage area of the RF transmitter, allowing RF waves emitted from antenna 140 to cover relatively larger geographical areas. Amplifier module 120 can also match the impedance of transmission path to the impedance of antenna 140 for maximum power transfer and optimizing the efficiency of the transmission.

TX filter 130 can receive amplified signal 106. TX filter 130 can be configured to suppress harmonics in amplified signal 106 (e.g., harmonics may be generated by amplifier module 120), filter out unwanted frequencies (e.g., frequencies different from the carrier frequency) and attenuate noise that might be present in amplified signal 106 to improve signal-to-noise ratio (SNR). The filtered version of amplified signal 106 can be outputted by TX filter 130 as output signal 108.

The receiver path can include at least a downconverter 114, an amplifier module 160 and the RX filter 150. Antenna 140 can receive a received signal 132 encoding data representing information and/or messages. The receiver path can filter, amplify and downconvert received signal 132 to generate a RX (receiver) signal 138 encoding the same data as received signal 132. Received signal 132 can be a RF signal.

RX filter 150 can receive received signal 132. RX filter 150 can be configured to filter out unwanted frequencies and attenuate noise that might be present in received signal 132 to generate filtered signal 134. Filtering received signal 132 to generate filtered signal 134 can also provide protection to amplifier module 160 by filtering out excessively strong out-of-band signals or signals with high levels of interference since amplifying such signals can risk damaging amplifier module 160.

Amplifier module 160 can receive filtered signal 134. Amplifier module 160 can be a low power amplifier configured to amplify signals with relatively low power levels. Using a low power amplifier in the receiver path can amplify filtered signal 134 to a level that can be processed by subsequent stages of the receiver path, such as downconverter 114, without introducing excessive noise or distortion. Also, using a low power amplifier in the receiver path can incur relatively less cost when compared to higher power amplifiers. Amplifier module 160 can amplify filtered signal 134 to generate an amplified signal 136. In one example, amplifier module 160 can be a low noise amplifier. Downconverter 114 can receive amplified signal 136. Downconverter 114 can be configured to convert amplified signal 136 into a RX signal 138 that has a lower frequency than TX signal 102. Downconverter 114 can send RX signal 138 to a controller or processor for further decoding.

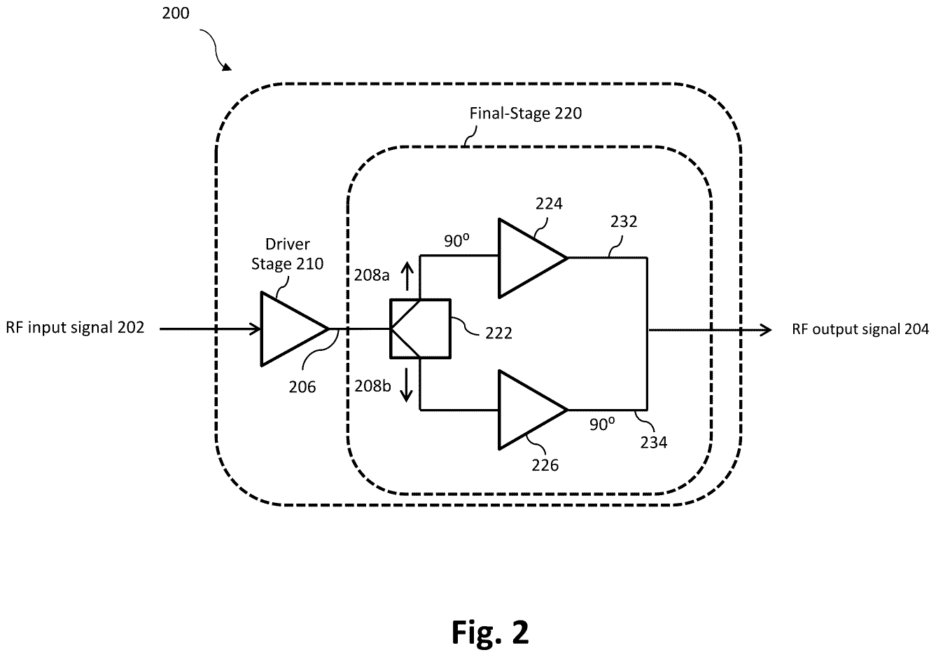

FIG. 2 is a diagram showing an example of a two-stage power amplifier 200 in one embodiment. An amplifier module 120 and another amplifier module 160 are shown in FIG. 1. Two-stage power amplifier 200 can be an implementation of amplifier module 120 and amplifier module 160 in FIG. 1. Two-stage power amplifier 200 can include a driver stage 210 (“driver 210”) and a final stage 220 (can also be referred to as output stage). Two-stage power amplifier 200 can receive a RF input signal 202. As an example, the RF input signal 202 can be the upconverted signal 104. Two-stage power amplifier 200 can amplify RF input signal 202 to generate an RF output signal 204, where RF output signal 204 has a higher signal strength than RF input signal 202. The difference in signal strengths between RF input signal 202 and RF output signal 204 can be dependent on the gain of two-stage power amplifier 200. As an example, RF input signal 202 can be upconverted signal 104 in FIG. 1, and RF output signal 204 can be amplified signal 106 in FIG. 1. Two-stage power amplifier 200 can be an integrated circuit (IC) implemented by semiconductor devices. Driver stage 210 and final stage 220 can be integrated in the same IC.

In an aspect, the signal level of a signal is the strength or intensity of the signal that can be measured in decibels (dB) or volts. The signal level of a signal can indicate how strong or weak a signal is at a particular point in a system. For example, in audio applications, the signal level of an audio signal can be referred to as the volume of a sound. On the other hand, a gain of a signal is an amount of increase in amplitude or power of the signal in response to being processed by an amplifier or other components configured to amplify signals. The gain can be a measure of how much an amplifier amplifies or boosts a signal compared to its input.

Driver stage 210 can receive RF input signal 202. Driver stage 210 can be configured to boost the signal level of RF input signal 202 to a target level for an attached antenna (e.g., antenna 140 in FIG. 1) to transmit wirelessly. The boosted signal generated by driver 210 can be outputted as amplified signal 206. Driver stage 210 can be implemented by a Gallium Arsenide (GaAs) device or GaAs transistor.

Final stage 220 can receive amplified signal 206. Final stage 220 can be configured to further boost amplified signal 206 to generate RF output signal 204. Final stage 220 can send RF output signal 204 to a load, such as antenna 140 in FIG. 1. Final stage 220 can be configured to amplify RF output signal 204 while maintaining relatively low distortion and high fidelity. In one or more embodiments, final stage 220 can include one or more power matching networks for matching the impedance of two-stage power amplifier 200 to the impedance of the load receiving RF output signal 204 in order to maximize power transmission efficiency.

Final stage 220 can include a splitter 222, an amplifier 224 and an amplifier 226. Final stage 220 can be implemented by a Doherty amplifier such that amplifier 224 can be a peak amplifier and amplifier 226 can be a main amplifier. In one embodiment, amplifier 224 can be a class C power amplifier and amplifier 226 can be a class AB power amplifier. In one or more embodiments, amplifiers 224 and 226 can be implemented by Gallium Nitride (GaN) devices or GaN transistors, including but not limited to Gallium Nitride Metal Semiconductor Field-effect transistors (GaN MOSFET), GaN high-electron-mobility transistor (HEMT), GaN heterostructure field-effect transistor (HFET), etc. For instance, each of the amplifier 224 and the amplifier 226 can be implemented by a Doherty amplifier.

In one embodiment, amplifier 224 can have a periphery size that ranges from the periphery size of amplifier 226 (e.g., device periphery ratio of 1:1) up to a periphery size equivalent to twice the periphery size of amplifier 226 (e.g., device periphery ratio of 1:2). In one embodiment, drain voltages of driver stage 210 and final stage 220 can be 50V.

Splitter 222 can receive amplified signal 206 from driver stage 210. Splitter 222 can be configured to generate a main input signal 208a and a peak input signal 208b using amplified signal 206. In one embodiment, splitter 222 can be a 90-degree hybrid coupler, or a quadrature coupler, configured as a power splitter to perform a 3-dB (e.g., equal) power split, such as dividing an input signal (e.g., amplified signal 206) evenly between two output ports with 3 dB coupling. The output signals, such as the main input signal 208a and the peak input signal 208b, can have a phase difference of 90 degrees. Main input signal 208 a can be a 90-degree shift version of amplified signal 206, and peak input signal 208b can be identical to, and/or in-phase with, amplified signal 206. In some examples, splitter 222 can further include a high absorption load (not shown) that isolates one of the ports of splitter 222 such that reflections from final stage 220 towards driver stage 210 can be absorbed by the high absorption load.

Amplifier 224 can be configured to amplify main input signal 208a to generate an amplified main signal 232. Amplifier 226 can be configured to amplify peak input signal 208b to generate an amplified peak signal 234. In one embodiment, amplifiers 224, 226 can be identical such that amplifiers 224, 226 can perform the same level of amplification, such as increasing the amplitudes of main input signal 208a and peak input signal 208b by the same amount. The outputs of amplifiers 224, 226 can be combined to form RF output signal 204. Amplified main signal 232 and amplified peak signal 234 can be combined to generate the RF output signal 204.

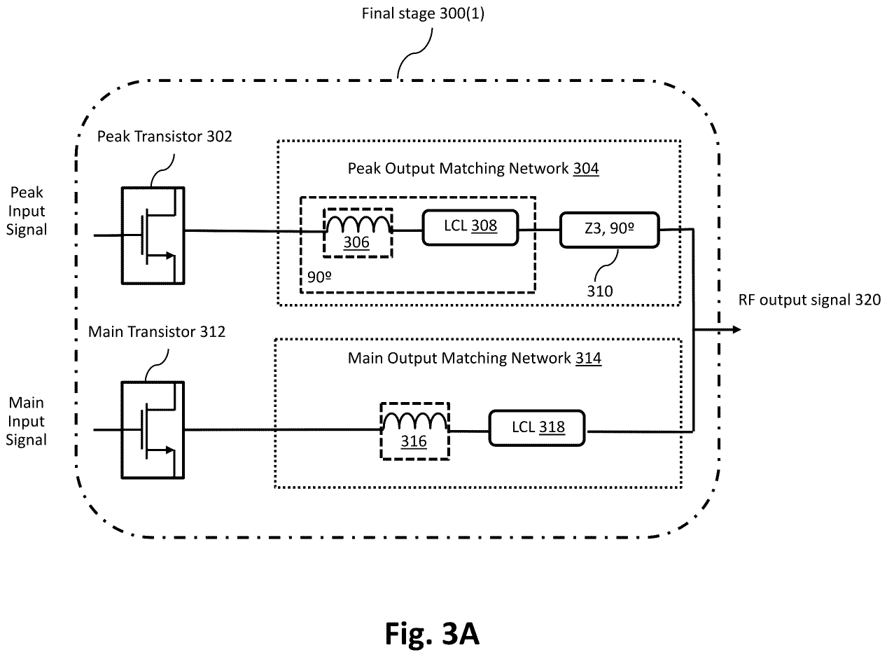

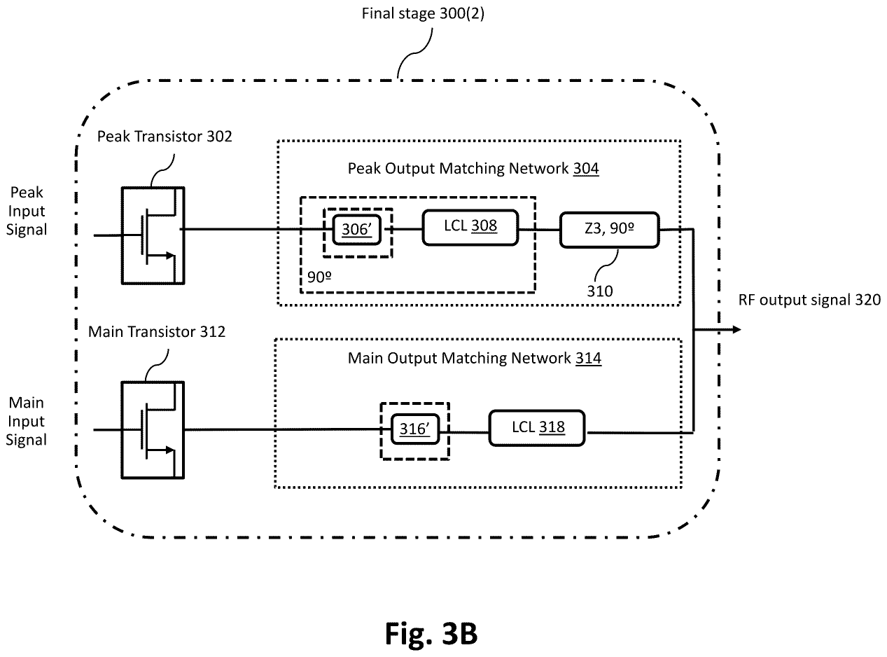

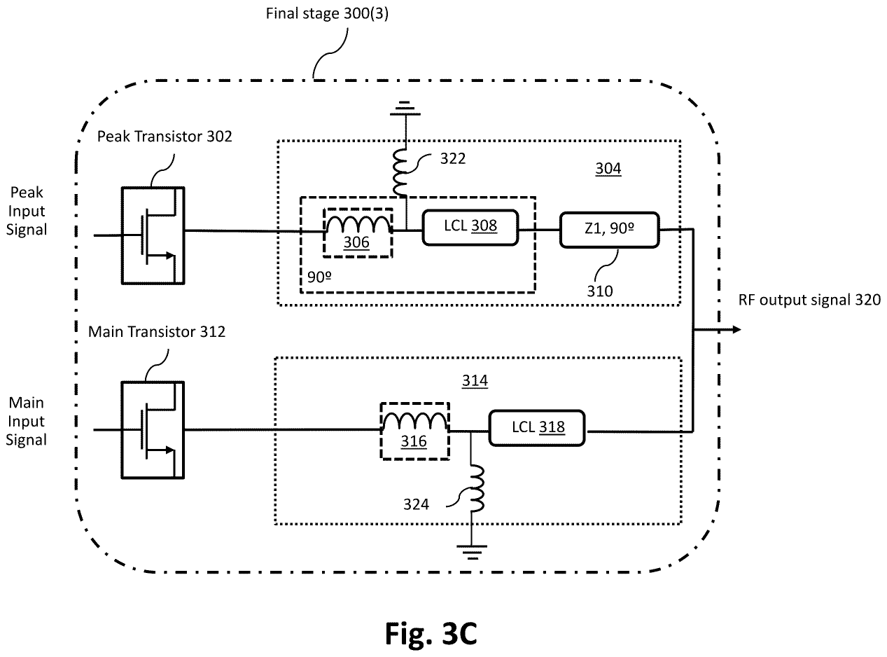

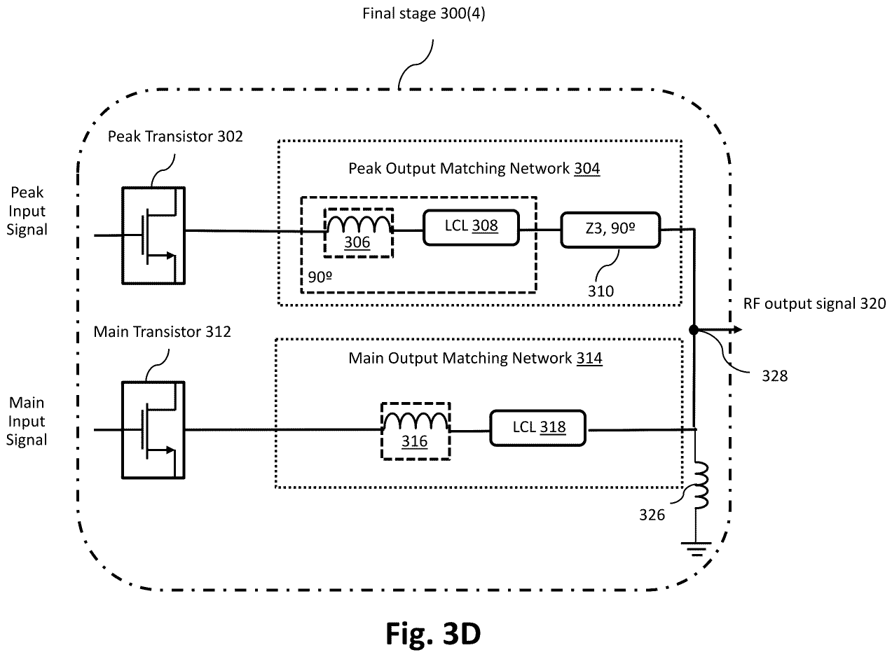

FIG. 3A is a diagram showing an example of the final stage 300(1) with matching networks in one embodiment. The final stage 300(1) with matching networks has enhanced bandwidth performance. For instance, the final stage 300(1) can be implemented as the final stage 220 in FIG. 2. The final stage 300(1) can be implemented with various semiconductor technologies such as GaN and laterally-diffused metal-oxide semiconductor (LDMOS).

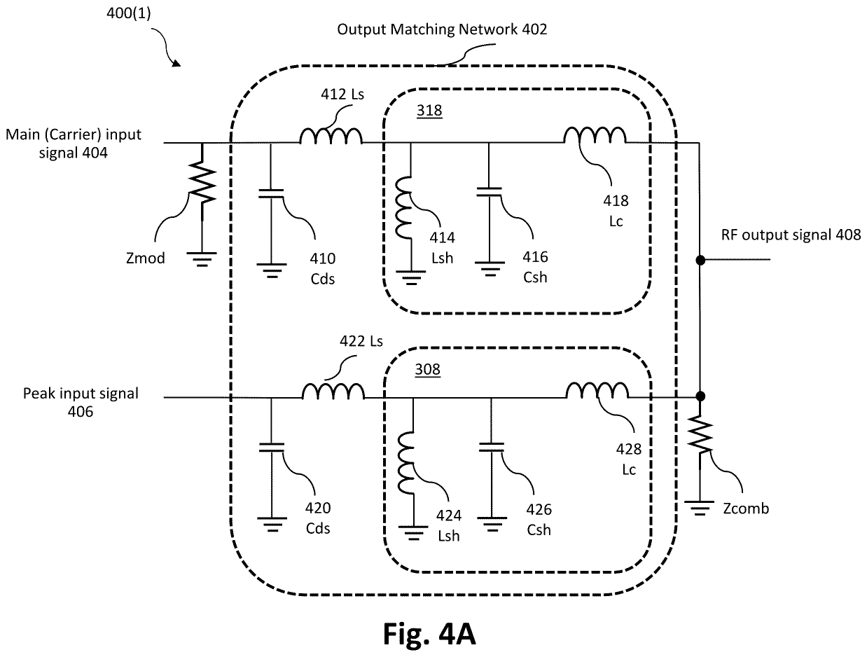

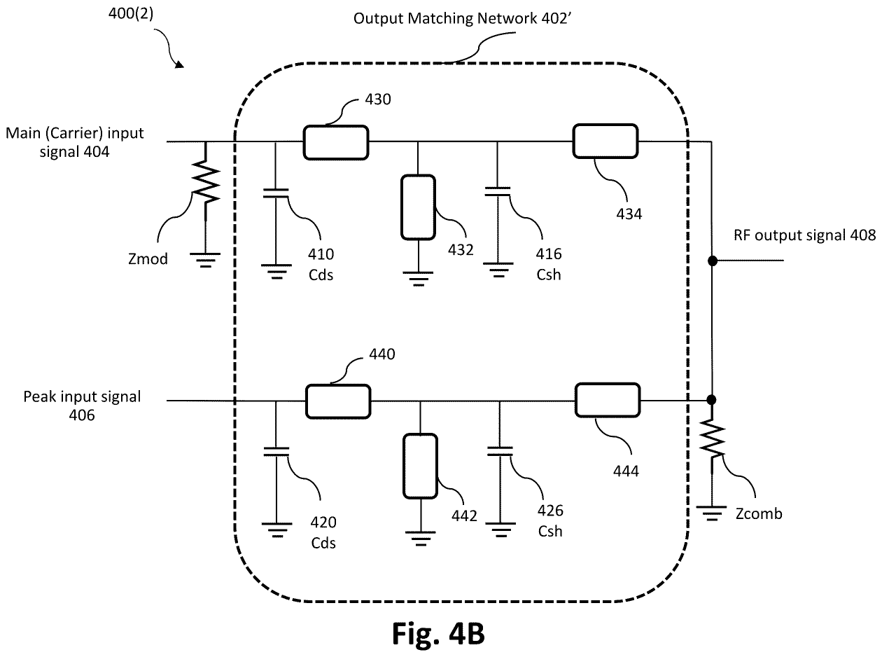

Final stage 300(1) can include a peak amplifier path and a main amplifier path. The peak amplifier path can include a peak transistor 302 and a peak output matching network 304 coupled to the peak transistor 302. The peak transistor 302 can be configured to amplify the peak input signal. The peak output matching network 304 can include a first series inductor 306, a first inductor-capacitor-inductor (LCL) section 308, and an impedance 310 with an impedance value of Z3. As an example, the impedance 310 can include another LCL section 308. Additional details of the first inductor-capacitor-inductor (LCL) section 308 are given with reference to FIG. 4. The first series inductor 306, the first inductor-capacitor-inductor (LCL) section 308, and the impedance 310 can be coupled in sequence.

The main amplifier path can include a main transistor 312 and a main output matching network 314 coupled to the main transistor 312. The main output matching network 314 can include a second series inductor 316 and a second inductor-capacitor-inductor (LCL) section 318 coupled to the second series inductor 316. Additional details of the second inductor-capacitor-inductor (LCL) section 318 are given with reference to FIG. 4.

Main input signal can enter the main amplifier path to be amplified and processed by the output matching network 304, and peak input signal can enter the peak amplifier path to be amplified and processed by the main output matching network 314. Output signals of the peak amplifier path and the main amplifier path can be combined to generate the RF output signal 320 (which can correspond to the RF output signal 204 in FIG. 2).

FIG. 3B is a diagram showing another example of the final stage 300(2) with matching networks in one embodiment. The configuration of the final stage 300(2) in FIG. 3B is similar to the configuration of the final stage 300(1) in FIG. 3A. Components with same reference numbers are the same in FIG. 3A and FIG. 3B. The differences between FIG. 3A and FIG. 3B are as follows.

In final stage 300(2), peak output matching network 304 uses a first microstrip transmission line device 306′ to replace the first series inductor 306. Moreover, main output matching network 314 uses a second microstrip transmission line device 316′ to replace the second series inductor 316.

A microstrip transmission line is a type of electrical transmission line used to carry high-frequency signals, typically in RF (radio frequency) and microwave circuits. It can include a conducting strip placed over a dielectric substrate, with a ground plane on the bottom. This structure allows the transmission of electromagnetic waves while maintaining controlled impedance. Compared to inductors, microstrip transmission line devices can transmit electromagnetic waves without significant energy storage. At high frequencies, inductors can have parasitic effects (e.g., self-resonance, stray capacitance). However, microstrip transmission line devices can support high-frequency signal propagation with controlled impedance.

FIG. 3C is a diagram showing an example of the final stage 300(3) with matching networks and drain bias inductors in one embodiment. The configuration of the final stage 300(3) in FIG. 3C is similar to the configuration of the final stage 300(1) in FIG. 3A. Components with same reference numbers are the same in FIG. 3A and FIG. 3B. The differences between FIG. 3A and FIG. 3C are as follows.

Peak output matching network 304 further includes a first drain bias inductor 322 is configured to bias the drain of the peak transistor 302. The first drain bias inductor 322 includes a first end and a second end. The first end is coupled between the first series inductor 306 and the first inductor-capacitor-inductor (LCL) section 308. The second end is connected to ground.

Main output matching network 314 further includes a second drain bias inductor 324. The second drain bias inductor 324 is configured bias the drain of the main transistor 312. The second drain bias inductor 324 includes a third end and a fourth end. The third end is coupled between the second series inductor 316 and the second inductor-capacitor-inductor (LCL) section 318. The fourth end is connected to the ground.

FIG. 3D is a diagram showing another example of the final stage 300(4) with matching networks and a drain bias inductor of one embodiment. The configuration of the final stage 300(4) in FIG. 3D is similar to the configuration of the final stage 300(1) in FIG. 3A. Components with the same reference numbers are the same in FIG. 3A and FIG. 3D. The differences between FIG. 3A and FIG. 3D are as follows.

The final stage 300(4) further includes a third drain bias inductor 326 configured to bias the drain of the peak transistor 302 and the drain of the main transistor 312 in combination. The third drain bias inductor 326 includes a fifth end and a sixth end. The fifth end is coupled to a combining node (i.e., output node) 328 of the peak amplifier path and the main amplifier path. The sixth end is connected to the ground.

FIG. 4A is a diagram showing an example circuit 400(1) including a matching network 402 in one embodiment. The output matching network can be implemented with various semiconductor technologies such as GaN and LDMOS technologies. The circuit 400(1) can include two parallel paths, i.e., the main (carrier) amplifier path and the peak amplifier path. Main (carrier) input signal 404 enters the main (carrier) amplifier path. Peak input signal 406 enters the peak amplifier path. The output signals of the main (carrier) amplifier path and the peak amplifier path can be combined as a RF output signal 408 (which can correspond to the RF output signal 204 in FIG. 2 and the RF output signal 320 in FIG. 3).

The circuit 400(1) can include a modulation impedance Zmod, the output matching network 402, and a combining impedance Zcomb. The output matching network 402 can be configured to transform the modulated impedance (Zmod) of the main (carrier) amplifier to the combining node impedance (Zcomb) at Output Back-Off (OBO) operation.

Main (carrier) amplifier path can include the modulation impedance Zmod and a first section of the output matching network 402 which includes a first parasitic drain-source capacitor 410 with a capacitance Cds, a first series inductor 412 with an inductance Ls, a first shunt inductor 414 with an inductance Lsh, a first shunt capacitor 416 with a capacitance Csh, and a first characteristic inductor 418 with an inductance Lc. The modulation impedance Zmod is coupled between an input node of the main (carrier) amplifier path and the ground. The first parasitic drain-source capacitor 410 is coupled between the input node and the ground. One end of the first series inductor 412 is coupled to the input node. The other end of the first series inductor 412 is coupled to one end of the first shunt inductor 414. The other end of the first shunt inductor 414 is coupled to the ground. One end of the first shunt capacitor 416 is coupled to a common node of the first series inductor 412 and the first shunt inductor 414. The other end of the first shunt capacitor 416 is coupled to the ground. One end of the first characteristic inductor 418 is coupled to a common node of the first series inductor 412, the first shunt inductor 414, and the first shunt capacitor 416. The other end of the first characteristic inductor 418 is coupled to an output node of the output matching network 402.

In one example, the first shunt inductor 414 with an inductance Lsh, the first shunt capacitor 416 with a capacitance Csh, and the first characteristic inductor 418 with an inductance Lc can correspond to the first LCL section 308 in FIG. 3.

Peak amplifier path can include a second section of the output matching network 402 which includes a second parasitic drain-source capacitor 420 with a capacitance Cds, a second series inductor 422 with an inductance Ls, a second shunt inductor 424 with an inductance Lsh, a second shunt capacitor 426 with a capacitance Csh, and a second characteristic inductor 428 with an inductance Lc.

The second parasitic drain-source capacitor 420 is coupled between an input node of the peak amplifier path and the ground. One end of the second series inductor 422 is coupled to the input node. The other end of the second series inductor 422 is coupled to one end of the second shunt inductor 424. The other end of the second shunt inductor 424 is coupled to the ground. One end of the second shunt capacitor 426 is coupled to a common node of the second series inductor 422 and the second shunt inductor 424. One end of the second characteristic inductor 428 is coupled to a common node of the second series inductor 422, the second shunt inductor 424 and the second shunt capacitor 426. The other end of the second characteristic inductor 428 is coupled to the output node of the output matching network 402. The combining impedance Zcomb is coupled between the output node and the ground.

In one example, the second shunt inductor 424 with an inductance Lsh, the second shunt capacitor 426 with a capacitance Csh, and the second characteristic inductor 428 with an inductance Lc can correspond to the second LCL section 318 in FIG. 3.

Example values of components in circuit 400(1) can be as follows. In one embodiment, Zmod can be 300-400 Ohms. Ls can be 5-8 nH. Lsh can be 5-8 nH. Csh can be 1-1.15 pF. Lc can be 5-8 nH.

The output RF signals of the main (carrier) amplifier path and the peak amplifier path are then combined to achieve Doherty amplifier performance at back-off operation.

FIG. 4B is a diagram showing an example circuit 400(2) including a matching network 402′ in one embodiment. The configuration of the circuit 400(2) in FIG. 4B is similar to the configuration of the circuit 400(1) in FIG. 4A. Components with same reference numbers are the same in FIG. 4A and FIG. 4B. The differences between FIG. 4A and FIG. 4B are as follows.

Instead of using inductors, the main (carrier) amplifier path includes a third microstrip transmission line device 430, a fourth microstrip transmission line device 432, and a fifth microstrip transmission line device 434. The peak amplifier path includes a sixth microstrip transmission line device 440, a seventh microstrip transmission line device 442, and an eighth microstrip transmission line device 444.

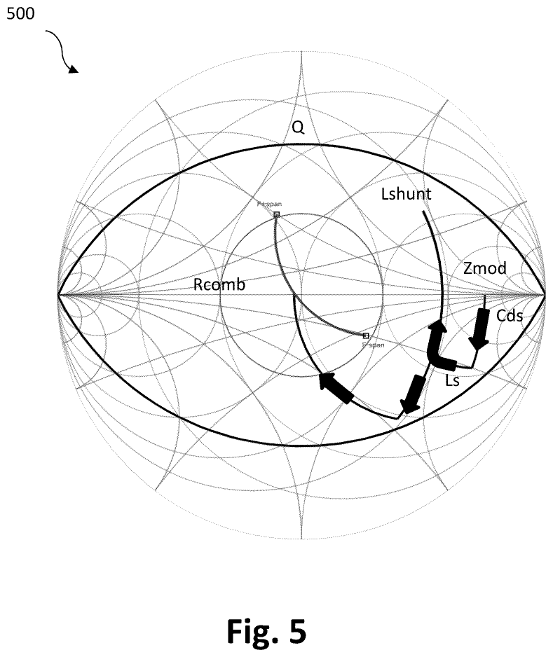

FIG. 5 is a diagram 500 showing a Smith chart representing the impedance matching trajectory in the RF circuit design of one embodiment, in the context of improving bandwidth for power amplifies. This visualization corresponds to an analysis of the impedance at the final stage (e.g., the final stage 220 in FIG. 2) in a Doherty configuration. One objective for the smith chart is to choose values for the components so that the circuit remains within lower values of Q.

The diagram 500 shows a network of intersecting circles characteristic of a Smith chart, which is used for visualizing complex impedance and admittance transformations. The outermost circle represents the normalized impedance boundary, with movement toward the center indicating improved matching and bandwidth. The Q curve in the Smith chart represents the resonant frequency of a circuit (e.g., the circuit 400(1) in FIG. 4). Q value is a measure of the quality of resonance and indicates how closely the circuit is tuned to a specific frequency. A higher Q value indicates a narrower bandwidth, while a lower Q value indicates a broader bandwidth. In a conventional Q matching network without series inductors (e.g., the first series inductor 412 and the second series inductor 422 in FIG. 4), impedance trajectories tend to move further from the center, leading to narrower bandwidths. The diagram 500 shows that with the series inductors (e.g., the first series inductor 412 and the second series inductor 422 in FIG. 4), the impedance trajectory can be kept closer to the Smith chart's center, which aligns with the strategy of lowering Q to achieve a broader frequency response.

The arrows in the Smith chart illustrate how the output matching network (e.g., the output matching network 402 in FIG. 4) with the series inductors (e.g., the first series inductor 412 and the second series inductor 422 in FIG. 4) shifts the impedance transformation. Instead of resonating out the parasitic drain-source capacitance (Cds) with a shunt inductor (e.g., the first shunt inductor 414 and the second shunt inductor 424 in FIG. 4), the output matching network (e.g., the output matching network 402 in FIG. 4) introduces a series inductance (Ls), which redirects the matching trajectory inward toward the center of the Smith chart.

The output matching network (e.g., the output matching network 402 in FIG. 4) results in improved bandwidth performance, as indicated by the more centralized impedance trace in the Smith Chart. The trajectory of impedance transformation remains beneficial regardless of the specific process, supporting an improvement in bandwidth and efficiency. By ensuring a more controlled impedance transition, the output matching network (e.g., the output matching network 402 in FIG. 4) contributes to maintaining high efficiency over a broader frequency range, reducing dispersive effects in traditional topologies without series inductors (e.g., the first series inductor 412 and the second series inductor 422 in FIG. 4).

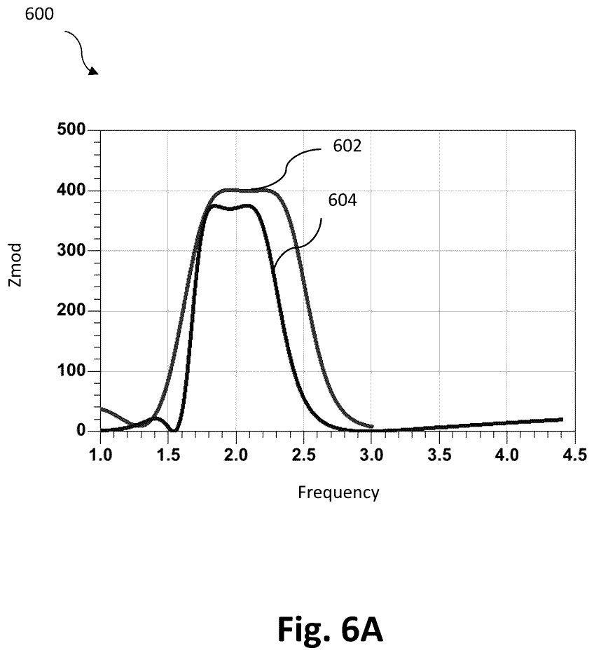

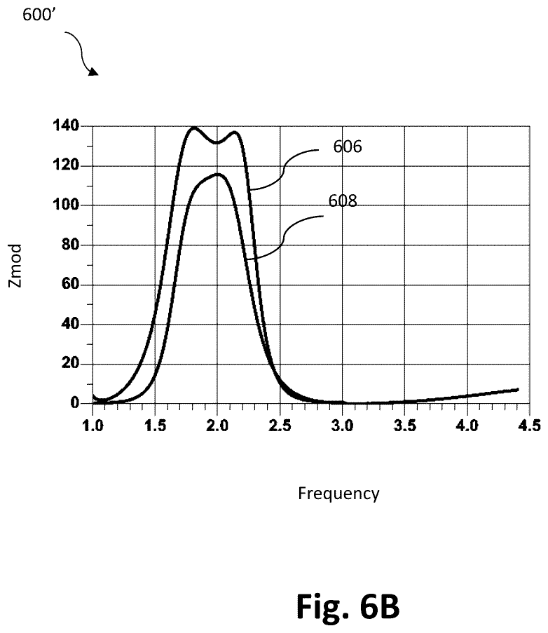

FIG. 6A shows a diagram 600 illustrating a comparison between the bandwidth performance of a two-stage power amplifier with a matching network with series inductors and the bandwidth performance of a two-stage power amplifier with a matching network without series inductors. In this example, the two-stage power amplifier is implemented with GaN devices.

As shown in FIG. 6A, the vertical axis represents the modulation impedance Zmod in Ohms, while the horizontal axis represents frequency in Giga Hertz (GHz). Curve 602 represents the bandwidth performance of a two-stage power amplifier with a matching network (e.g., the output matching network 402 in FIG. 4) with series inductors. Curve 604 represents a two-stage power amplifier with a matching network without series inductors.

FIG. 6B shows a diagram 600′ illustrating another comparison between the bandwidth performance of a two-stage power amplifier with a matching network with series inductors and the bandwidth performance of a two-stage power amplifier with a matching network without series inductors. In this example, the two-stage power amplifier is implemented with LDMOS devices.

As shown in FIG. 6B, the vertical axis represents the modulation impedance Zmod in

Ohms, while the horizontal axis represents frequency in GHz. Curve 606 represents the bandwidth performance of a two-stage power amplifier with a matching network (e.g., the output matching network 402 in FIG. 4) with series inductors. Curve 608 represents a two-stage power amplifier with a matching network without series inductors.

As described above, the series inductors within the output matching network play a role in modifying the impedance transformation characteristics of the final stage. The series inductance effectively lowers the impedance, which is helpful for reducing the Voltage Standing Wave Ratio (VSWR) transformation requirements in the subsequent matching stages. Lower VSWR transformation leads to more efficient power transfer and reduced signal reflections, improving the overall performance of the amplifier. Moreover, by lowering the impedance plane, the output matching network can achieve a broader frequency range as shown by curve 602 compared to curve 604, reducing performance degradation caused by impedance mismatch over different operating frequencies.

The incorporation of a high series inductor helps mitigate bandwidth compression issues typically caused by VSWR-related mismatch. Such a configuration provides higher Zmod values, ensuring that the amplifier can operate efficiently across a wider bandwidth.

The diagram 600 in FIG. 6A and the diagram 600′ in FIG. 6B illustrate the impact of series inductors on the output matching network, emphasizing its role in lowering the impedance plane, enhancing VSWR transformation efficiency, and expanding the operational bandwidth. Such a configuration of the output matching network of the final stage of the amplifier significantly improves impedance matching, promoting broader frequency response and improved power amplifier performance. The configurations with the drain biasing inductors make it more efficient and easier to implement, particularly in high-frequency applications. For instance, in power amplifiers that operates within the 3.4-4 GHz range, such a configuration may demonstrate high efficiency.

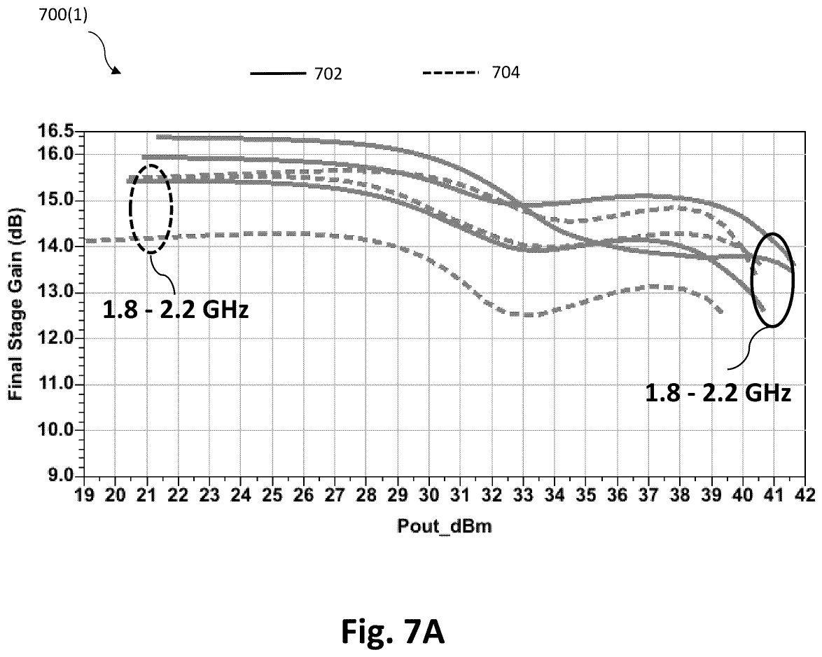

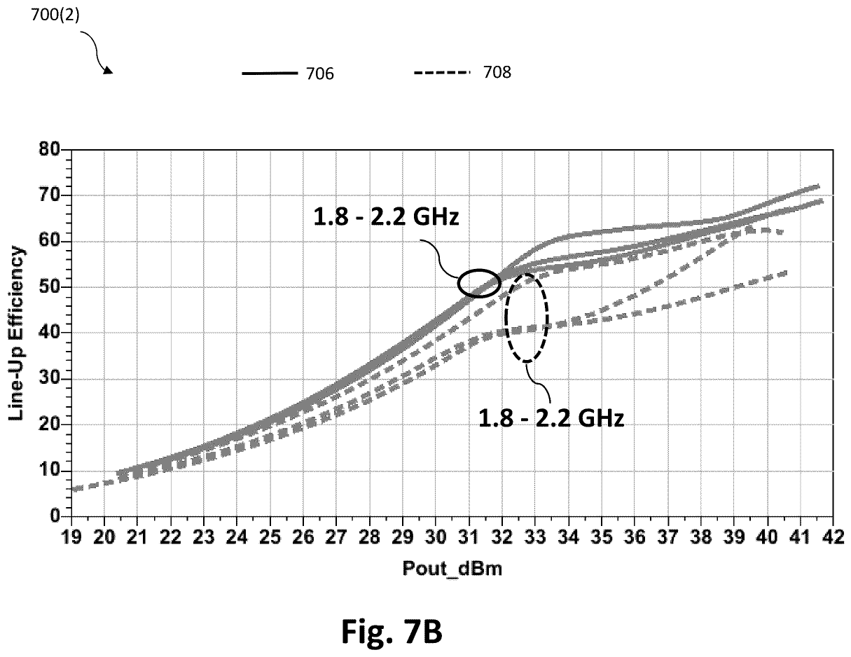

FIG. 7A shows a diagram 700(1) illustrating a comparison between the large signal performance of a two-stage power amplifier with a matching network with series inductors and the large signal performance of a two-stage power amplifier with a matching network without series inductors. Solid curves 702 represent the large signal performance of a two-stage power amplifier with a matching network with series inductors. Dashed curves 704 represent the large signal performance of a two-stage power amplifier with a matching network without series inductors.

FIG. 7B shows a diagram 700(2) illustrating another comparison between the large signal performance of a two-stage power amplifier with a matching network with series inductors and the large signal performance of a two-stage power amplifier with a matching network without series inductors. Solid curves 706 represent the large signal performance of a two-stage power amplifier with a matching network with series inductors. Dashed curves 708 represent the large signal performance of a two-stage power amplifier with a matching network without series inductors.

In both FIG. 7A and FIG. 7B, the vertical axis represents line-up efficiency, while the horizontal axis represents Pout in decibel-milliwatts (dBm). In the implementations, simulations are conducted to analyze gain versus power and efficiency versus power. FIG. 7A and FIG. 7B demonstrate that the output matching network with series inductors provides more consistent performance across different frequencies. Each line in the diagram corresponds to a specific frequency, such as 1.82 GHz and 2.2 GHz. As shown in FIG. 7A and FIG. 7B, both efficiency and gain are more uniform at average power levels—usually where users will evaluate performance. The solid curves (702 and 706) represent the performance of the output matching network with series inductors, while the dashed curves (704 and 708) represent the performance of the output matching network without series inductors. For instance, in the output matching network without series inductors, efficiency at 31 dBm varies significantly, ranging from 40% to 50%. However, in the output matching network with series inductors, efficiency is consistently around 50%, showing minimal variation across frequencies. This improved consistency makes the output matching network with series inductors helpful for wideband applications.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

### EXAMPLES

Clause 1. An integrated circuit comprising: a driver stage configured to receive an input signal and provide an amplified signal based on the input signal; a final stage coupled to the driver stage and configured to generate an output signal, the final stage comprising: a splitter configured to receive the amplified signal from the driver stage and split the amplified signal into a main input signal and a peak input signal; a main amplifier coupled to the splitter and configured to receive the main input signal and provide an amplified main signal; a peak amplifier coupled to the splitter and configured to receive the peak input signal to provide an amplified peak signal; a main output matching network coupled to the main amplifier, the main output matching network comprising a first series inductor; and a peak output matching network coupled to the peak amplifier, the peak output matching network comprising second series inductor.

Clause 2. The integrated circuit of clause 1, wherein the main input signal is a 90-degree shift version of the amplified signal, and the peak input signal is in-phase with the amplified signal.

Clause 3. The integrated circuit of clause 1 or 2, wherein the final stage is implemented by Gallium Nitride (GaN) devices and/or laterally-diffused metal-oxide semiconductor (LDMOS) devices.

Clause 4. The integrated circuit of any of clauses 1-3, wherein the first series inductor is implemented by a first microstrip transmission line device, and the second series inductor is implemented by a second microstrip transmission line device.

Clause 5. The integrated circuit of any of clauses 1-4, wherein each of the main amplifier and the peak amplifier is implemented by a Doherty amplifier.

Clause 6. The integrated circuit of any of clauses 1-5, wherein the main output matching network further comprises: a first inductor-capacitor-inductor section coupled to the first series inductor; and an impedance coupled between the first inductor-capacitor-inductor section and an output of the final stage.

Clause 7. The integrated circuit of any of clauses 1-6, wherein the peak output matching network further comprises a second inductor-capacitor-inductor section coupled between the second series inductor and the output of the final stage.

Clause 8. The integrated circuit of any of clauses 1-7, wherein the main output matching network further comprises: a first drain bias inductor comprising: a first end coupled between the first series inductor and the first inductor-capacitor-inductor section; and a second end connected to ground; and a second drain bias inductor comprising: a third end coupled between the second series inductor and the second inductor-capacitor-inductor section; and a fourth end connected to the ground.

Clause 9. The integrated circuit of any of clauses 1-8, wherein the final stage further comprises a third drain bias inductor coupled between the output of the final stage and ground.

Clause 10. A system comprising: a plurality of antennas; a transmission path coupled to the plurality of antennas, the transmission path comprising an amplifier module, the amplifier module comprising: a driver stage configured to receive an input signal and provide an amplified signal based on the input signal; a final stage coupled to the driver stage and configured to generate an output signal, the final stage comprising: a splitter configured to receive the amplified signal from the driver stage and split the amplified signal into a main input signal and a peak input signal; a main amplifier coupled to the splitter and configured to receive the main input signal and provide an amplified main signal; a peak amplifier coupled to the splitter and configured to receive the peak input signal to provide an amplified peak signal; a main output matching network coupled to the main amplifier, the main output matching network comprising a first series inductor; and a peak output matching network coupled to the peak amplifier, the peak output matching network comprising second series inductor.

Clause 11. The system of clause 10, wherein the main input signal is a 90-degree shift version of the amplified signal, and the peak input signal is in-phase with the amplified signal.

Clause 12. The system of clause 10 or 11, wherein the final stage is implemented by Gallium Nitride (GaN) devices and/or laterally-diffused metal-oxide semiconductor (LDMOS) devices.

Clause 13. The system of any of clauses 10-12, wherein the first series inductor is implemented by a first microstrip transmission line device, and the second series inductor is implemented by a second microstrip transmission line device.

Clause 14. The system of any of clauses 10-13, wherein the main output matching network further comprises: a first inductor-capacitor-inductor section coupled to the first series inductor; and an impedance coupled between the first inductor-capacitor-inductor section and an output of the final stage.

Clause 15. The system of any of clauses 10-14, wherein the peak output matching network further comprises a second inductor-capacitor-inductor section coupled between the second series inductor and the output of the final stage.

Clause 16. The system of any of clauses 10-15, wherein the main output matching network further comprises: a first drain bias inductor comprising: a first end coupled between the first series inductor and the first inductor-capacitor-inductor section; and a second end connected to ground; and a second drain bias inductor comprising: a third end coupled between the second series inductor and the second inductor-capacitor-inductor section; and a fourth end connected to the ground.

Clause 17. The system of any of clauses 10-16, wherein the final stage further comprises a third drain bias inductor coupled between the output of the final stage and ground.

Clause 18. A system comprising: a plurality of antennas; a receiver path coupled to the plurality of antennas, the receiver path comprising an amplifier module, the amplifier module comprising: a driver stage configured to receive an input signal and provide an amplified signal based on the input signal; a final stage coupled to the driver stage and configured to generate an output signal, the final stage comprising: a splitter configured to receive the amplified signal from the driver stage and split the amplified signal into a main input signal and a peak input signal; a main amplifier coupled to the splitter and configured to receive the main input signal and provide an amplified main signal; a peak amplifier coupled to the splitter and configured to receive the peak input signal to provide an amplified peak signal; a main output matching network coupled to the main amplifier, the main output matching network comprising a first series inductor; and a peak output matching network coupled to the peak amplifier, the peak output matching network comprising second series inductor.

Clause 19. The system of clause 18, the main output matching network further comprises: a first inductor-capacitor-inductor section coupled to the first series inductor; and an impedance coupled between the first inductor-capacitor-inductor section and an output of the final stage.

Clause 20. The system of clause 18 or 19, wherein the peak output matching network further comprises a second inductor-capacitor-inductor section coupled between the second series inductor and the output of the final stage.

What is claimed is:

1. An integrated circuit comprising:
a driver stage configured to receive an input signal and provide an amplified signal based on the input signal; and
a final stage coupled to the driver stage and configured to generate an output signal, the final stage comprising:
a splitter configured to receive the amplified signal from the driver stage and split the amplified signal into a main input signal and a peak input signal;
a main amplifier coupled to the splitter and configured to receive the main input signal and provide an amplified main signal;
a peak amplifier coupled to the splitter and configured to receive the peak input signal to provide an amplified peak signal;
a main output matching network coupled to the main amplifier, the main output matching network comprising a first series inductor; and
a peak output matching network coupled to the peak amplifier, the peak output matching network comprising second series inductor.

2. The integrated circuit of claim 1, wherein the main input signal is a 90-degree shift version of the amplified signal, and the peak input signal is in-phase with the amplified signal.

3. The integrated circuit of claim 1, wherein the final stage is implemented by Gallium Nitride (GaN) devices and/or laterally-diffused metal-oxide semiconductor (LDMOS) devices.

4. The integrated circuit of claim 1, wherein the first series inductor is implemented by a first microstrip transmission line device, and the second series inductor is implemented by a second microstrip transmission line device.

5. The integrated circuit of claim 1, wherein each of the main amplifier and the peak amplifier is implemented by a Doherty amplifier.

6. The integrated circuit of claim 1, wherein the main output matching network further comprises:
a first inductor-capacitor-inductor section coupled to the first series inductor; and
an impedance coupled between the first inductor-capacitor-inductor section and an output of the final stage.

7. The integrated circuit of claim 6, wherein the peak output matching network further comprises a second inductor-capacitor-inductor section coupled between the second series inductor and the output of the final stage.

8. The integrated circuit of claim 7, wherein the main output matching network further comprises:
a first drain bias inductor comprising:
a first end coupled between the first series inductor and the first inductor-capacitor-inductor section; and
a second end connected to ground; and
a second drain bias inductor comprising:
a third end coupled between the second series inductor and the second inductor-capacitor-inductor section; and
a fourth end connected to ground.

9. The integrated circuit of claim 1, wherein the final stage further comprises a third drain bias inductor coupled between an output of the final stage and ground.

10. A system comprising:
a plurality of antennas; and
a transmission path coupled to the plurality of antennas, the transmission path comprising an amplifier module, the amplifier module comprising:
a driver stage configured to receive an input signal and provide an amplified signal based on the input signal; and
a final stage coupled to the driver stage and configured to generate an output signal, the final stage comprising:
a splitter configured to receive the amplified signal from the driver stage and split the amplified signal into a main input signal and a peak input signal;
a main amplifier coupled to the splitter and configured to receive the main input signal and provide an amplified main signal;
a peak amplifier coupled to the splitter and configured to receive the peak input signal to provide an amplified peak signal;
a main output matching network coupled to the main amplifier, the main output matching network comprising a first series inductor; and
a peak output matching network coupled to the peak amplifier, the peak output matching network comprising second series inductor.

11. The system of claim 10, wherein the main input signal is a 90-degree shift version of the amplified signal, and the peak input signal is in-phase with the amplified signal.

12. The system of claim 10, wherein the final stage is implemented by Gallium Nitride (GaN) devices and/or laterally-diffused metal-oxide semiconductor (LDMOS) devices.

13. The system of claim 10, wherein the first series inductor is implemented by a first microstrip transmission line device, and the second series inductor is implemented by a second microstrip transmission line device.

14. The system of claim 10, wherein the main output matching network further comprises:
a first inductor-capacitor-inductor section coupled to the first series inductor; and
an impedance coupled between the first inductor-capacitor-inductor section and an output of the final stage.

15. The system of claim 14, wherein the peak output matching network further comprises a second inductor-capacitor-inductor section coupled between the second series inductor and the output of the final stage.

16. The system of claim 15, wherein the main output matching network further comprises:
a first drain bias inductor comprising:
a first end coupled between the first series inductor and the first inductor-capacitor-inductor section; and
a second end connected to ground; and
a second drain bias inductor comprising:
a third end coupled between the second series inductor and the second inductor-capacitor-inductor section; and
a fourth end connected to ground.

17. The system of claim 10, wherein the final stage further comprises a third drain bias inductor coupled between an output of the final stage and ground.

18. A system comprising:
a plurality of antennas; and
a receiver path coupled to the plurality of antennas, the receiver path comprising an amplifier module, the amplifier module comprising:
a driver stage configured to receive an input signal and provide an amplified signal based on the input signal; and
a final stage coupled to the driver stage and configured to generate an output signal, the final stage comprising:
a splitter configured to receive the amplified signal from the driver stage and split the amplified signal into a main input signal and a peak input signal;
a main amplifier coupled to the splitter and configured to receive the main input signal and provide an amplified main signal;
a peak amplifier coupled to the splitter and configured to receive the peak input signal to provide an amplified peak signal;
a main output matching network coupled to the main amplifier, the main output matching network comprising a first series inductor; and
a peak output matching network coupled to the peak amplifier, the peak output matching network comprising second series inductor.

19. The system of claim 18, the main output matching network further comprises:
a first inductor-capacitor-inductor section coupled to the first series inductor; and
an impedance coupled between the first inductor-capacitor-inductor section and an output of the final stage.

20. The system of claim 19, wherein the peak output matching network further comprises a second inductor-capacitor-inductor section coupled between the second series inductor and the output of the final stage.
